(19) United States
(12) Patent Application Publication
(10) Pub. No.: US 2011/0143485 A1
(43) Pub. Date: Jun. 16, 2011

(54) METHOD OF MANUFACTURING SOLID-STATE IMAGING APPARATUS

(75) Inventor: Koichi Tazoe, Sagamihara-shi (JP)

(73) Assignee: CANON KABUSHIKI KAISHA, Tokyo (JP)

(21) Appl. No.: 12/941,678

(22) Filed: Nov. 8, 2010

(30) Foreign Application Priority Data
Dec. 11, 2009 (JP) 2009-282285

(51) Int. Cl. H01L 31/0232

(52) U.S. Cl. 438/72; 257/E31.127

(57) ABSTRACT

The method of manufacturing the solid-state imaging apparatus of the present invention includes: forming elements of an imaging region and a peripheral region on a substrate; forming a plurality of wiring patterns such that the wiring patterns of the peripheral region are denser than those of the imaging region; and forming an insulating film interposed between the wiring patterns. Further, the manufacturing method includes: etching and removing at least a part of the insulating film on the peripheral region; and planarizing a surface of the insulating film by a CMP process.

### BACKGROUND OF THE INVENTION

1. Field of the Invention

The present invention relates to a method of manufacturing a MOS-type solid-state imaging apparatus.

2. Description of the Related Art

A CCD-type or CMOS-type solid-state imaging apparatus is used as an image sensor such as a digital still camera and a digital video camera. There is a requirement of forming such image sensor into a multi-pixel and miniaturized (microminiaturized) structure.

Japanese Patent Application Laid-Open No. 2005-012189 discloses a CMOS-type solid-state imaging apparatus having a multilayer wiring structure and describes that the wiring pattern of an imaging region has a lower density configuration than that of the wiring pattern of a peripheral region. Here, according to the Patent document 1, an insulating film is deposited on a wiring layer by a CVD process and then planarized by a CMP process; and thereby the insulating film is formed under the interlayer lens.

Japanese Patent Application Laid-Open No. 2006-294765 discloses a solid-state imaging apparatus having a multilayer wiring structure using a CMOS technology and describes that when a planarization layer is formed on an upper layer of the wiring layer, a step is formed according to the density of the wiring layer pattern. In order to reduce steps, Patent document 2 discloses a technique by which a light transmitting dummy pattern is formed on a light-receiving portion whose wiring layer pattern has a low density so as to reduce density variations in the pattern between the light-receiving portion and the peripheral region of the light-receiving portion for planarization.

Here, the present inventors have found the following. First, according to Japanese Patent Application Laid-Open No. 2005-012189, the wiring pattern of the imaging region has a lower density than that of the wiring pattern of the peripheral region. Therefore, when an insulating film is formed by the CVD process, a step occurs on a surface of the insulating film between the imaging region and the peripheral region. When planarization is performed by the CMP process in a state in which a step exists, dishing occurs and the film thickness may be uneven. Such an uneven thickness of interlayer insulation film causes the multilayer wiring structure to be different in optical path between a central portion and a peripheral portion of the imaging region. Thus, color unevenness occurs due to light interference.

According to the technique disclosed in Japanese Patent Application Laid-Open No. 2006-294765 by which a dummy pattern is arranged in the light-receiving portion, reflection, refraction, absorption, and the like of light may cause a reduction in incident light reaching the light-receiving portion and a reduction in sensitivity.

In light of this, an object of the present invention is to provide a method of manufacturing the solid-state imaging apparatus in which even if a wiring pattern has a density variation between the imaging region and the peripheral region, variations in film thickness after planarization of the insulating film on the wiring layer are reduced and color unevenness is suppressed.

### SUMMARY OF THE INVENTION

According to one aspect of the present invention, a manufacturing method of a solid-state imaging apparatus comprises steps of: forming an imaging region including a plurality of photoelectric conversion elements arranged on a substrate and a peripheral circuit region arranged at a periphery of the imaging region; forming a plurality of wiring patterns such that a density of the wiring patterns in the peripheral circuit region is larger than a density of the wiring patterns in the imaging region; forming an insulating film filling between the plurality of wiring patterns above the imaging region and the peripheral circuit region; removing by etching at least a part of the insulating film arranged in the peripheral circuit region; and planarizing a surface of the insulating film by CMP process, after the step of removing by etching at least the part of the insulating film.

Other features and advantages of the present invention will be apparent from the following description taken in conjunction with the accompanying drawings, in which like reference characters designate the same or similar parts throughout the figures thereof.

Further features of the present invention will become apparent from the following description of exemplary embodiments with reference to the attached drawings.

### BRIEF DESCRIPTION OF THE DRAWINGS

FIGS. 1A, 1B and 1C are schematic sectional views of a solid-state imaging apparatus describing a manufacturing method of a first embodiment.

FIGS. 2D and 2E are schematic sectional views of the solid-state imaging apparatus describing the manufacturing method of the first embodiment.

FIG. 3 is a plan view describing the solid-state imaging apparatus of the first embodiment.

FIG. 4 is a schematic sectional view of a solid-state imaging apparatus of a second embodiment.

The accompanying drawings, which are incorporated in and constitute a part of the specification, illustrate embodiments of the invention and, together with the description, serve to explain the principles of the invention.

### DESCRIPTION OF THE EMBODIMENTS

Preferred embodiments of the present invention will now be described in detail in accordance with the accompanying drawings.

The method of manufacturing the solid-state imaging apparatus of the present invention includes forming elements of an imaging region and a peripheral region on a substrate, forming a plurality of wiring patterns such that the wiring patterns of the peripheral region are denser than those of the imaging region, and forming an insulating film interposed between the wiring patterns. Further, the manufacturing method includes etching and removing at least a part of the insulating film on the peripheral region, and planarizing a surface of the insulating film by a CMP process. Even if the wiring patterns have density variations between the imaging region and the peripheral region, such a manufacturing method can suppress reduction in sensitivity of a photoelectric conversion element and can reduce variations in film thickness after planarization of the insulating film on the wiring layer. Thus, color unevenness can be suppressed and a high-sensitive solid-state imaging apparatus can be manufactured.

### First Embodiment

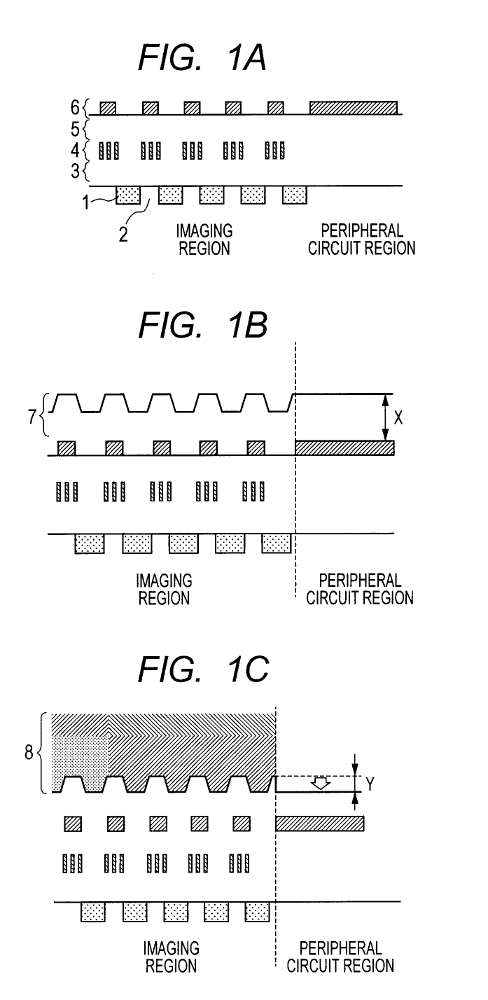

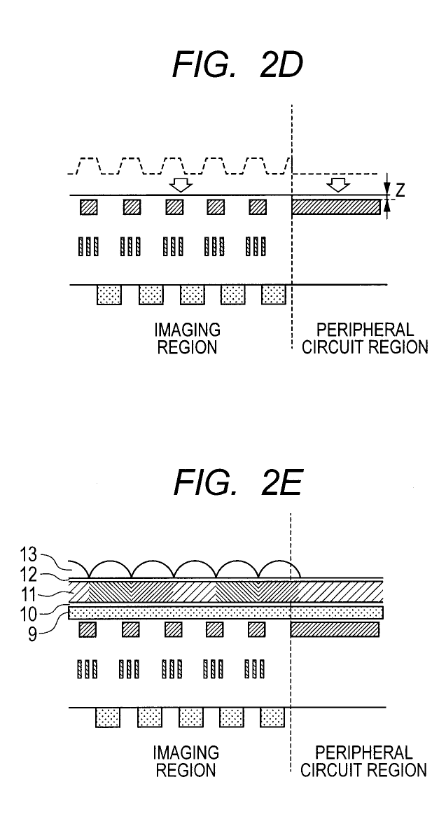

The method of manufacturing the solid-state imaging apparatus according to the present embodiment is described using FIGS. 1A to 1C, and 2D and 2E. FIGS. 1A to 1C, 2D and 2E are schematic sectional views of a CMOS-type solid-state imaging apparatus having a multilayer wiring structure. FIGS. 1A to 1C, 2D and 2E illustrate only the essential parts of the structure.

In FIG. 1A, an imaging region and a peripheral region including elements such as a photo diode and a transistor are formed on a substrate. The imaging region includes a photodiode 1 which is a photoelectric conversion element and an element isolation region 2 formed on the substrate. The photodiodes 1 are two dimensionally arranged. The peripheral region includes a scanning circuit, an amplifier and the like. The peripheral region may include an optical black region in which the photodiode is shielded by a light shielding film to obtain a reference signal. The present embodiment does not illustrate circuits arranged in the peripheral region. In FIG. 1A, a multilayer wiring structure is formed on such a substrate. The multilayer wiring structure includes a first insulating film 3, a first wiring pattern 4 arranged on an upper portion of the first insulating film 3, a second insulating film 5 covering the first wiring pattern 4, and a second wiring pattern 6 arranged on an upper portion of the second insulating film 5. The first insulating film 3 and the second insulating film 5 are, for example, made of a silicon oxide film and can be served as an interlayer insulation film. The first wiring pattern 4 and the second wiring pattern 6 each are made of a plurality of conductive patterns, can serve as wiring and can also be served as the light shielding film. The first wiring pattern 4 and the second wiring pattern 6 are made of aluminum and are formed by performing photolithography and dry-etching on an aluminum film formed on the first insulating film 3 or the second insulating film 5. A well-known manufacturing method can be applied to the manufacturing method. Note that the present embodiment does not illustrate a contact connecting the substrate and the first wiring pattern 4 or a through hole connecting the first wiring pattern 4 and the second wiring pattern 6.

Here, in FIG. 1A, the second wiring pattern 6 of the present embodiment is the uppermost wiring pattern and has a pattern covering the peripheral region. The density of the second wiring pattern 6 is higher in the peripheral region than in the imaging region. Here, the density refers to an area of the wiring pattern per unit area, viewed two-dimensionally.

Then, in FIG. 1B, a third insulating film 7 covering the second wiring pattern 6 is formed by a CVD process. The third insulating film 7, for example, is made of a silicon oxide film. The film thickness of the third insulating film 7 formed at this time is assumed to be X(Å). The film thickness X(Å) is a film thickness from the upper surface of the second wiring pattern 6 to the upper surface of an insulating film deposited. That is, the film thickness X(Å) is an insulating film deposition film thickness. Here, the surface of third insulating film 7 has asperities depending on the shape of the second wiring pattern 6.

Then, as illustrated in FIG. 1C, a photoresist 8 having an opening to the peripheral region is formed on the third insulating film 7. Then, part of the third insulating film 7 of the peripheral region not covered with the photoresist 8 is etched and removed by dry-etching. The differences of the film thickness (etching amount) when the third insulating film 7 is removed is assumed to be Y(Å). Note that the opening portion of the photoresist 8 may be provided on an upper portion of not only the peripheral region but also the imaging region. Alternatively, the photoresist 8 may be provided inside the peripheral region.

Then, the photoresist 8 is removed and the entire surface of the third insulating film 7 is planarized by the CMP process (FIG. 2D). The film thickness of the insulating film after planarization (insulating film thickness after CMP process) is assumed to Z(Å). Like the film thickness X(Å), Z(Å) is a film thickness from the upper surface of the second wiring pattern 6.

Subsequently, as illustrated in FIG. 2E, a protecting film 9 made of, for example, a plasma oxynitride film or a plasma nitride film is formed on the planarized third insulating film 7. This protecting film 9 may include an anti-reflection film made of a plasma oxynitride film or the like. Then, a first planarization film 10 made of resin, a color filter 11 and a second planarization film 12 are formed on the protecting film 9 in this order. Then, a micro lens 13 is formed on the second planarization film 12. A well-known manufacturing method can be applied to the manufacturing method. Thus, the solid-state imaging apparatus of the present embodiment is completed.

By such a manufacturing method, part of the insulating film of the peripheral region having a dense wiring pattern is removed by etching and then planarization is performed thereon by a CMP process. Thereby, planarization can be uniformly performed even on a layout having a density variation of wiring pattern. Therefore, the film thickness of the multilayer wiring structure in the entire imaging region, namely, the optical path can be uniform. Thus, generation of color unevenness can be suppressed and the optical characteristics of a photoelectric conversion element can be uniform.

Here, the present inventors have found that the film thickness X(Å) of the insulating film is preferably twice or more and four times or less of the removed film thickness Y(Å). In particular, approximately three times thereof provides the most remarkable effect of suppressing color unevenness caused by variations in film thickness. For example, when the insulating film has a film thickness X of 15000 (Å) and a removed film thickness Y of 5000 (Å), and the final insulating film has a film thickness Z of 2500 (Å), an image free from color unevenness was obtained.

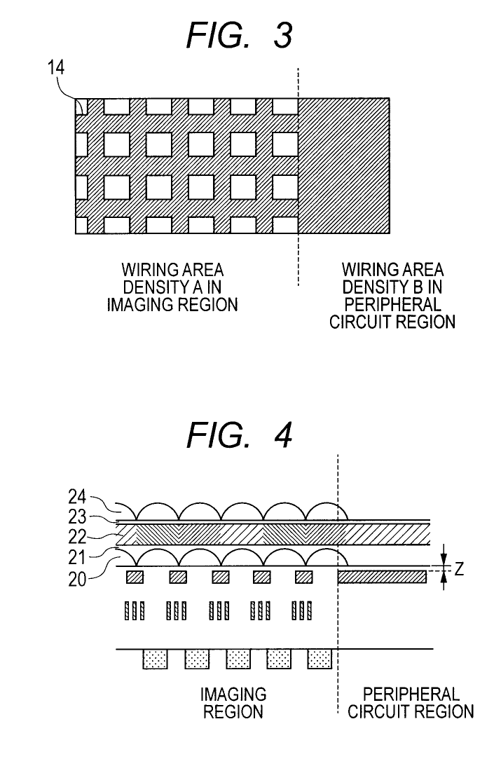

Now, by using FIG. 3, the density of the second wiring pattern 6 is described. FIG. 3 is a schematic view of the imaging region and the peripheral region each viewed from above when the second wiring pattern 6 is provided. It is assumed that in the wiring pattern 14 constituting the second wiring pattern 6, the imaging region has a density A per unit area and the peripheral region has a density B per unit area. According to the manufacturing method of the present embodiment, when the density ratio A/B is equal to or less than 0.5, a much greater effect is exhibited. That is, the smaller the density ratio A/B, the more the variations of the surface of the third insulating film 7 illustrated in FIG. 1B increase. However, such a ratio of the second wiring pattern 6 means that the opening portion of the photodiode 1 is wide, and thus it is understood that the sensitivity of the photodiode 1 can be improved. Therefore, even if the wiring pattern density A of the imaging region is reduced in order to improve sensitivity, use of the manufacturing method of the present embodiment can easily suppress the generation of variations in film thickness after planarization by the CMP process. Thus, the sensitivity can be improved and degrading optical characteristics such as color unevenness can be suppressed.

### Second Embodiment

The present embodiment is described by using FIG. 4. The present embodiment is different from the first embodiment in that the present embodiment has an interlayer lens layer. In FIG. 4, description of the same components as those in the first embodiment (FIGS. 1 and 2) is omitted.

In FIG. 4, an interlayer lens layer 20 including a plurality of interlayer lenses, for example, using a plasma nitride film is formed on the second insulating film 7 planarized by the same manufacturing method as that of the first embodiment. Here, each interlayer lens of the interlayer lens layer 20 is formed in one-to-one correspondence with the photodiode 1. Subsequently, a first planarization film 21, a color filter 22, a second planarization film 23 and a micro lens 24 are formed on the interlayer lens layer 20 in this order. A well-known manufacturing method can be applied to the manufacturing method. This interlayer lens layer 20 can also have a function as a protecting film. Moreover, the interlayer lens layer 20 may have an anti-reflection layer made of, for example, a plasma oxynitride film.

As described in the present embodiment, even if two lenses (an interlayer lens and a micro lens) are formed per photodiode 1, the optical path is uniform in the multilayer wiring structure, and thus degrading optical characteristics such as color unevenness can be suppressed. Further, a lower layer of the interlayer lens layer 20 is planarized, and thus the interlayer lens can be formed with good accuracy.

Here, Table 1 illustrates image evaluation results of a CMOS-type solid-state imaging apparatus in a central portion and a peripheral portion of the imaging region under the conditions that the film thickness X is 15000 (Å), the removed film thickness Y is 5000 (Å), and the density ratio A/B of the second wiring pattern 6 is 0.35 in the configuration of the second embodiment.

TABLE 1

Z(Å)

| | Central | Peripheral | Color |
|---|---|---|---|
| | portion | portion | unevenness |
| Second | 2500 | 2550 | Not present |
| embodiment | | | |
| Comparative | 2500 | 4500 | Present |
| example | | | |

In Table 1, the film thickness Z is a film thickness of the third insulating film 7 after planarization by a CMP process (see FIG. 2D). The film thickness Z is a film thickness from the upper surface of the second wiring pattern 6. The film thickness of the second embodiment planarized by the same manufacturing method as the first embodiment has a difference of 50 (Å) between the central portion and the peripheral portion. On the contrary, the film thickness of the comparative example planarized not by the same manufacturing method as the first embodiment but only by the CMP process has a difference of 2000 (Å) between the central portion and the peripheral portion. Here, the wavelength of the visible light used by the solid-state imaging apparatus is specifically in a range of about 400 nm or more and 750 nm or less (Optical Technical Term Dictionary published by The Optronics Co., Ltd.). A film thickness difference of 2000 (Å) indicates one-fourth or more of the variations of the visible light wavelength. Therefore, light intensity is changed by interference which causes color unevenness. In contrast to this, a film thickness difference of 50 (Å) in the configuration of the present embodiment indicates one-fourth or less of the variations of the visible light wavelength and thus it is considered that color unevenness was reduced. Note that z may be 0. In other word, the upper surface of the planarized insulating film may match the upper surface of the wiring pattern.

As described above, according to the method of manufacturing the solid-state imaging apparatus of the present invention, even if a wiring pattern has a density variation between the imaging region and the peripheral region, reduction in sensitivity of the photoelectric conversion element is suppressed and variations in film thickness after planarization of the insulating film on the wiring layer can be reduced. Thus, color unevenness can be suppressed and a high-sensitive solid-state imaging apparatus can be manufactured.

A configuration of each embodiment can be combined as needed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-282285, filed Dec. 11, 2009, which is hereby incorporated by reference herein in its entirety.

What is claimed is:

1. A manufacturing method of a solid-state imaging apparatus comprising steps of:
forming elements of an imaging region including a plurality of photoelectric conversion elements arranged on a substrate and a peripheral circuit region arranged at a periphery of the imaging region;
forming a plurality of wiring patterns such that a density of the wiring patterns in the peripheral circuit region is higher than a density of the wiring patterns in the imaging region;
forming an insulating film filling between the plurality of wiring patterns above the imaging region and the peripheral circuit region;
removing by etching at least a part of the insulating film arranged in the peripheral circuit region; and
planarizing a surface of the insulating film by CMP process, after the step of removing by etching at least the part of the insulating film.

2. The manufacturing method according to claim 1, further comprising
a step of forming, above the insulating film, a plurality of lenses each one corresponding to each one of the plurality of photoelectric conversion elements, after the step of planarizing the surface of the insulating film by CMP process.

3. The manufacturing method according to claim 1, further comprising
a step of forming a protective film above the insulating film, after the step of planarizing the surface of the insulating film by CMP process.

4. The manufacturing method according to claim 1, wherein
a thickness of the insulating film formed by the step of forming the insulating film is twice or more and four times or less of a thickness of the insulating film after the step of removing by etching at least the part of the insulating film.

5. The manufacturing method according to claim 4, wherein
a thickness of the insulating film formed by the step of forming the insulating film is three times as large as a thickness of the insulating film after the step of removing by etching at least the part of the insulating film.

6. The manufacturing method according to claim 3, wherein
the protective film includes an anti-reflection film.
